(19) United States
(12) Patent Application Publication
(10) Pub. No.: US 2020/0301039 A1
(43) Pub. Date: Sep. 24, 2020

(54) SMALL FLOWLINES FOR NUCLEAR MAGNETIC RESONANCE MEASUREMENTS

(71) Applicant: Schlumberger Technology Corporation, Sugar Land, TX (US)

(72) Inventors: Yiqiao Tang, Belmont, MA (US); Yi-Qiao Song, Newton Center, MA (US); Martin Hurlimann, Newton, MA (US); Christopher Harrison, Auburndale, MA (US); Marcus Hofheins Donaldson, Somerville, MA (US); Mark Flaum, Houston, TX (US)

(73) Assignee: Schlumberger Technology Corporation, Sugar Land, TX (US)

(21) Appl. No.: 16/825,736

(22) Filed: Mar. 20, 2020

Related U.S. Application Data
(60) Provisional application No. 62/821,172, filed on Mar. 20, 2019.

(51) Int. Cl. G01V 3/14; G01N 24/08; G01R 33/30

(52) U.S. Cl. CPC G01V 3/14; G01R 33/307; G01N 24/081

(57) ABSTRACT

Small-sized flowlines are provided for use in NMR apparatus. The small-sized flowlines can have a channel with an inner diameter or maximum width of less than 0.2 inch and can be made of sapphire, yttria-stabilized zirconia (YSZ), or extruded polyether ether ketone (PEEK), which are useful in high temperature, high pressure environments such as downhole in a geological formation.

### CROSS-REFERENCE TO RELATED APPLICATION(s)

The subject disclosure claims priority from U.S. Provisional Patent Appl. No. 62/821,172, filed on Mar. 20, 2019, entitled “SMALL FLOWLINES FOR NUCLEAR MAGNETIC RESONANCE MEASUREMENTS,” herein incorporated by reference in its entirety.

### FIELD

The subject disclosure relates to flowlines or channels used in nuclear magnetic resonance (NMR) apparatus that perform NMR measurements.

### BACKGROUND

NMR apparatus that employ small-sized flowlines are used in a variety of applications in multiple industries. In biomedical research for example, NMR relaxation measurements are performed with microcoils on capillary channels, where the sample volume may be as little as a few microliters (μL). Such small fluid channels pose significant challenges to the measurement, due to the large surface-to-volume ratio for the contained fluid.

In sampling tools for geological formations, flowline measurements are used to interrogate bulk fluid properties in downhole conditions. See U.S. Pat. No. 7,804,296 to Flaum et al. which is hereby incorporated by reference herein in its entirety.

A large body of literature on NMR measurements with small flowlines exists. By way of example, U.S. Pat. No. 6,097,188 to Sweedler et al. is entitled “Microcoil Based Micro-NMR Spectrometer and Method” describes an NMR apparatus having an analyte sample holder having a containment region that holds a volume of less than about 10 microliters. Other documents include, e.g., Haun, Jered B. et al., “Micro-NMR for rapid molecular analysis of human tumor samples,” Science Translational Medicine 3(71), (2011); and Lee, Hahko et al., “chip-NMR biosensor for detection and molecular analysis of cells,” Nature Medicine 14:8, pp 869-874 (2008); Wensink, Henk, et al., “Measuring reaction kinetics in a lab-on-a-chip by microcoil NMR,” Lab on a Chip 5.3, pp. 280-284 (2005).

In all prior art situations utilizing miniature (small-sized) flowlines (e.g., with inner diameter or maximum channel width of less than 0.2 inches), undesirable spectra artefacts in the NMR measurements are present.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Miniature (small-sized) flowlines are provided for NMR apparatus that do not introduce undesirable spectra artefacts when subjected to NMR measurements. The miniature flowlines may be used for oilfield NMR applications (including both uphole and downhole NMR equipment) over a wide range of temperatures and pressures, and in conjunction with a wide range of fluid samples, including hydrocarbons.

In embodiments, a miniature flowline is provided that has an inner diameter or maximum channel width of less than 0.2 inches.

In embodiments, a miniature flowline is formed from extruded polyether ether ketone (PEEK). The PEEK flowline may be annealed to 200° C. to permit the flowline to be used in high temperature environments, such as for downhole NMR measurements.

In embodiments, a miniature flowline is formed from synthetically-grown sapphire crystal, and the inner diameter or channel of the flowline is ground smooth to remove polygon-like edges.

In embodiments, a miniature flowline is formed from ytrria-stabilized zirconia (YSZ) ceramic.

In embodiments, NMR apparatus and devices and systems, such as uphole and downhole NMR equipment, are provided with a miniature flowline as described herein.

### BRIEF DESCRIPTION OF THE DRAWINGS

The subject disclosure is further described in the detailed description which follows, in reference to the noted plurality of drawings by way of non-limiting examples of the subject disclosure, in which like reference numerals represent similar parts throughout the several views of the drawings, and wherein:

FIG. 1A are plots of a series of T₂ relaxation spectra of dodecane samples at different temperatures in a flowline made by machining PEEK;

FIG. 1B are plots of a series of phased CPMG data of dodecane samples at the corresponding temperatures of the plots of FIG. 1A in the same machined PEEK flowline of FIG. 1A;

FIG. 2A are plots of T₂ relaxation spectra for water in two different diameter flowlines made of alumina;

FIG. 2B are plots of phased CPMG data for water in the two different diameter alumina flowlines of FIG. 2A;

FIG. 3A is a plot of the T₂ relaxation spectra for water in a small diameter flowline made of sapphire;

FIG. 3B is a plot of phased CPMG data for water in the small diameter sapphire flowline of FIG. 3A;

FIG. 4 is an image of the small-diameter sapphire flowline used in measuring the T₂ relaxation spectra of FIG. 3A and the phased CPMG data of FIG. 3B;

FIG. 5A are plots of a series of three T₂ relaxation spectra for water in a small diameter flowline made of YSZ where three different echo spacings were utilized in the NMR measurements of the experiment;

FIG. 5B are plots of phased CPMG data for water in the small diameter YSZ flowline of FIG. 5A;

FIG. 6 shows a machined PEEK flowline (on top) and a comparable extruded PEEK flowline (bottom);

FIG. 7A are plots of a series of six T₂ relaxation spectra for water in a small diameter flowline formed from extruded PEEK at different temperatures and pressures and using different echo spacings and dummy echoes in the CPMG sequence of the NMR measurements;

FIG. 7B are plots of phased CPMG data for water in the small diameter extruded PEEK flowline of FIG. 7A;

FIG. 8A are plots of a series of five T₂ relaxation spectra for dodecane in a small diameter extruded PEEK flowline at different temperatures and using different echo spacings and dummy echoes in the CPMG sequence of the NMR measurements;

FIG. 8B are plots of phased CPMG data for dodecane in the small diameter extruded PEEK flowline of FIG. 8A;

FIGS. 9A, 9B, 9C and 9D are plots of four different T₁-T₂ spectra for water samples in a small diameter extruded PEEK flowlinne at different temperatures;

FIG. 10 is a cross-sectional schematic diagram of a small diameter extruded PEEK flowline installed in a HPHT probe; and

FIG. 11 is a plot of an NMR measurement of dodecane density as a function of pressure.

FIG. 12 is a schematic view of an exemplary downhole wireline tool having a fluid sampling and analysis system.

FIG. 13 is a schematic view of an exemplary downhole drilling tool having a fluid sampling and analysis system.

FIG. 14 is a detailed view of the fluid sampling and analysis system of the tool of FIG. 12 and/or FIG. 13.

### DETAILED DESCRIPTION

The particulars shown herein are by way of example and for purposes of illustrative discussion of the examples of the subject disclosure only and are presented in the cause of providing what is believed to be the most useful and readily understood description of the principles and conceptual aspects of the subject disclosure. In this regard, no attempt is made to show details in more detail than is necessary, the description taken with the drawings making apparent to those skilled in the art how the several forms of the subject disclosure may be embodied in practice. Furthermore, like reference numbers and designations in the various drawings indicate like elements.

According to one aspect, in making NMR measurements to interrogate fluid properties, external factors, such as interactions between fluid molecules and the inner wall of the flowline should be minimized. In particular, since flowline NMR is a measurement of molecular dynamics, it is very sensitive to any abnormalities of magnetic susceptibility and surface defects of the flowline materials. Thus, according to one aspect, at least two primary considerations may be applied to a minatured (small-sized) flowline for NMR measurements.

First, the inner surface of the flowline which is in direct contact with the fluids under study can be configued to be smooth with reduced surface roughness or effective porosity. In this context, “smooth” means that the inner surface of the flowline is a regular or consistent surface that is free from projections, lumps, indentations or other surface defects that result in fast relaxation components in a measured relaxation spectrum. In other words, the surface roughness or effective porosity of the inner surface of the flowline is kept at a minimal level as any surface defect (a scratch, a dent, or a small bump) is a potential site for altering molecular trajectories that result in motion slowdowns and fast relaxation components in a measured relaxation spectrum.

Second, the material of the flowline should be non-magnetic, non-conductive, and ideally of zero magnetic susceptibility. Contamination of paramagnetic/ferromagnetic elements should be avoided. The paramagnetic/ferromagnetic elements, which can introduced either in the raw material of the flowline or during machining of the flowline, can create unwanted local magnetic fields that cause an accelerated decoherence of NMR signals (and therefore a fast relaxation).

When using a minaturized flowline for oilfield applications, such as for downhole NMR measurements of formation fluids or borehole fluids, a primary consideration involves the compatibility of the flowline with the downhole conditions and fluids. Thus, in one aspect, the material of the flowline can be selected such that the relaxation time of protons in the material of the flowline will be well below that of relaxation time of the protons in the formation fluids or borehole fluids. In addition, the flowline material of the flowline should be inert to common formation fluids and borehole fluids.

According to embodiments, the material of the flowline can be easily machinable. According to other embodiments, the material of the flowline can have good mechanical properties. Recommended material properties for a minaturized flowline for downhole NMR measurements are summarized in Table 1:

TABLE 1

| Recommend Material Property | Notes |
|---|---|
| Minimize introducing chemical impurities in | for reducing |
| the starting material and during machining | unwanted effects |
| Minimize disruption at inner surface | on NMR measurements |
| during machining | quirements |
| Non-conductive | |
| Near-zero magnetic suspectibility | |
| Inert to downhole fluid | for tools requirements |
| Good mechanical properties | |
| Easy to Machine | |

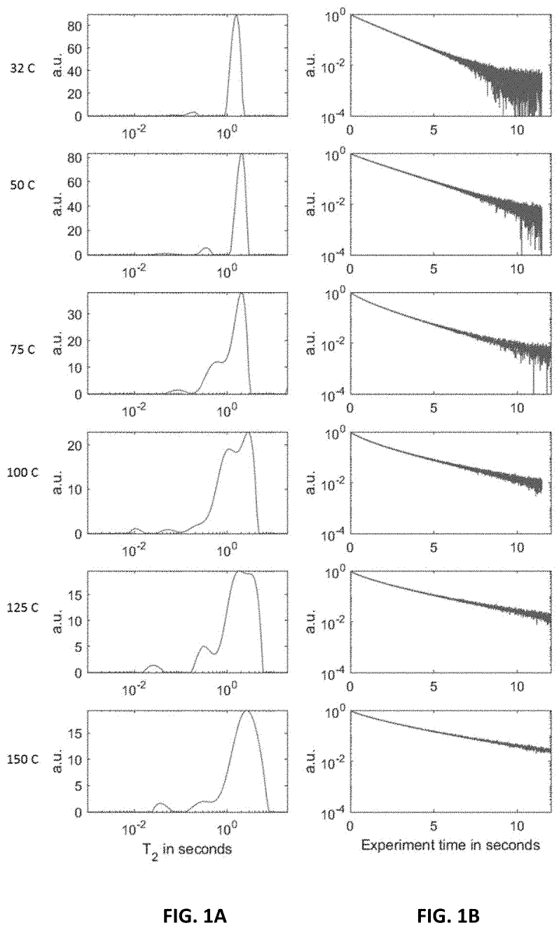

An example of a flowline for NMR measurements that does not satisfy the recommended material properties of Table 1 is a flowline machined from PEEK (polyether ether keton) stock and provided with a 1/16″ inner diameter. The machined PEEK flowline was used to perform the NMR measurements of FIGS. 1A and 1B. Specifically, the machined PEEK flowline was placed in a miniaturized NMR sensor fixture utilizing a Halbach-array magnet at 23-21 MHz proton NMR frequencies. Fluid comprising greater than 99.9% dodecane fluid was introduced into the machined PEEK flowline. The fluid was subjected to 1000 psi pressure and an NMR CPMG pulse sequence was utilized in order to find the T₂ relaxation time of the fluid. As shown in FIG. 1A, NMR relaxation measurements were taken at temperatures from 30° C. to 150° C. Corresponding phased CPMG data was also measured as shown in the plots of FIG. 1B. Since dodecane is a pure chemical compound, a sharp peak in the relaxation spectra should result from the NMR relaxation measurements. However, as shown in FIG. 1A, a broadened fluid peak was observed at 1 (10°) second and a minor fast relaxation artefact was present at approximately 100 ms at room temperature (top plot). This artefact progressively worsened at elevated temperatures and completely obscured the bulk fluid signals at temperatures above 75° C. These results show that the use of the machined PEEK flowline for the NMR measurements invalidates the obtained results at elevated temperatures.

According to embodiments, four different materials meeting the criteria of Table 1 were tested for suitability for a minaturized flowline for NMR measurements.

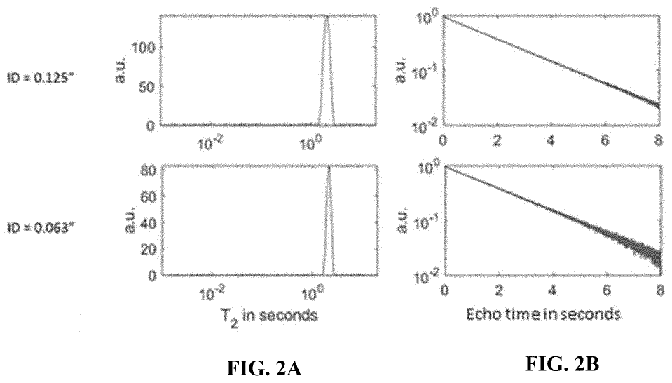

In a first embodiment, alumina was used as the material for the flowline. For example, an alumina ceramic is made by firing amorphous Al₂O₃ in a furnace. A first tube is formed from the alumina ceramic and has a 0.125 inch (round) outer diameter and 0.063 inch (round) inner diameter, and a second tube is formed from the alumina ceramic and has a 0.25 inch (round) outer diameter and 0.125 inch (round) inner diameter. Both the first and second tubes were filled with water and tested at 21° C. with the same miniaturized NMR sensor fixture described above with reference to the machined PEEK tube and the same NMR pulse sequence. The T₂ relaxation spectra and corresponding CPMG data for the water in the two tubes are shown in FIGS. 2A and 2B where a single relative sharp peak is seen. It is noted, however, that alumina lacks mechanical strength for downhole use and is particularly prone to failure in environments where shock and vibration are present. Accordingly, in one aspect, alumina can be used as a yardstick for characterizing other materials.

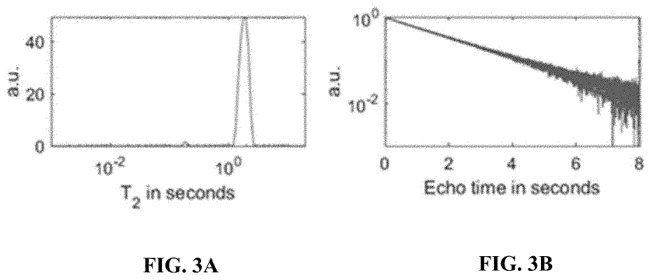

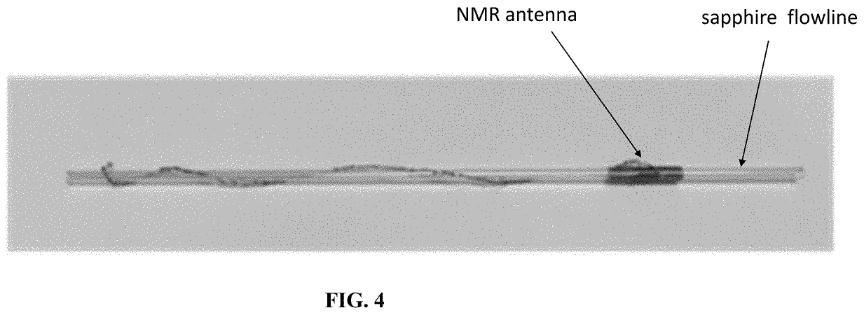

In a second embodiment, sapphire was used as the material for the flowline. Sapphire is widely deployed in downhole sampling tools and is also routinely used to make NMR sample-holders. A flowline formed from sapphire and having a 0.069 inch (round) inner diameter and 0.125 inch (round) outer diameter was filled with water and tested at room temperature and a pressure of 10 psi with the same miniaturized NMR sensor fixture described above with reference to the machined PEEK tube and the same NMR pulse sequence. The T₂ relaxation spectrum and corresponding CPMG data for the water in the sapphire flowline are shown in FIGS. 3A and 3B, respectively. Note that a large T₂ peak is seen at about 2 seconds, but a rather small fast relaxation component is also seen at about 200 ms. Origins of the artefact are not entirely clear, but upon close inspection, it was found that the inner diameter of the sapphire flowline had a polygon-like cross-section which is typical for an “as-grown” crystalline surface. Thus, according to one aspect, it is believed that sapphire is a suitable material for the small diameter flowline because the fast relaxation component is minimal. Furthermore, it is believed that grinding or other surface preparation can be applied to inner diameter surface of the sapphire flowline in order to eliminate the minimal fast relaxation component. A photograph of the sapphire flowline used in generating the plots of FIGS. 3A and 3B is seen in FIG. 4.

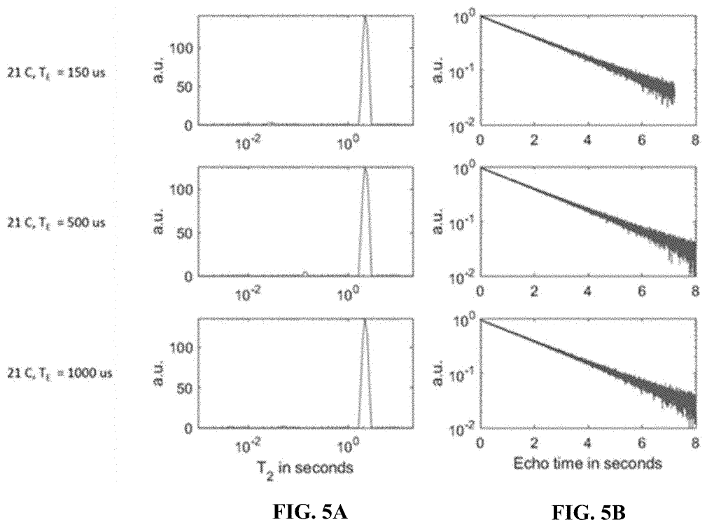

In a third embodiment, yttria-stabilized zirconia (YSZ) was used as the material for the flowline. A salient feature of YSZ is its capability to withstand 40,000 psi differential pressure across the wall of ther flowline without any pressure compensation. This material capability has the potential of greatly simplifying the design of the NMR sensor. A flowline formed from YSZ sapphire and having an approximately 0.118 inch (round) inner diameter and 0.197 inch (round) outer diameter was filled with water at tested at room temperature using different NMR echo spacings; i.e., T_{E}=150 μs, 500 μs, and 1000 μs. The T₂ relaxation spectra and corresponding CPMG data for the water in the YSZ flowline are shown in FIGS. 5A and 5B, Note that the large T₂ peak is seen with minimal fast relaxation components.

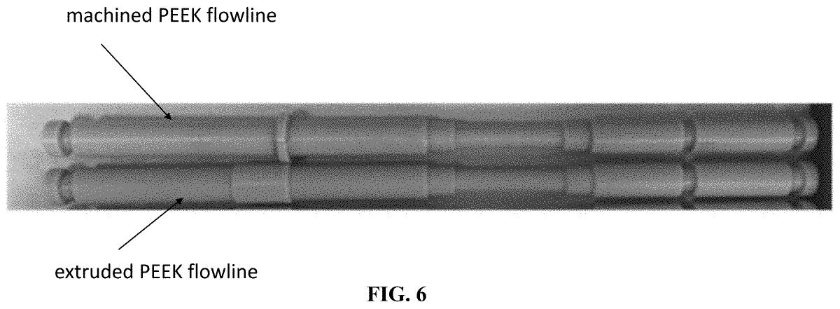

In a fourth embodiment, PEEK was used as the material for the flowline, and the flowline was formed by extrusion to construct an extruded thick-wall tube comprising PEEK. As part of the extrusion process, the PEEK material is pushed through a die of the desired cross-section. FIG. 6 depicts a machined PEEK flowline (top) and a comparable extruded PEEK flowline (bottom). Note that the extruded PEEK flowline (bottom) is better suited to be fit in a small-sized NMR sensor fixture.

According to one aspect, when making the extruded PEEK flowline, the inner diameter of the extruded PEEK flowline can be supported by a through-hole gauge pin and thus can be preserved in its post-extrusion condition. When a tube of extruded PEEK was subjected to temperature cycles of up to 150° C., a small (2%) shortening of the tube length was observed. At such elevated temperatures, the PEEK polymer began to melt and released strains inside the tube body. To avoid the probe deformation, other extruded PEEK flowlines were subjected to annealing using temperatures of 200° C. following the procedure in Table 2.

TABLE 2
Annealing procedure for extruded PEEK flowlines
PEEK annealing procedure

| Start temp (° C.) | Set temp (° C.) | Ramp rate (° C./min) | Time (hours) |
|---|---|---|---|
| 20 | 150 | 0.1 | 21.7 |
| 150 | 150 | 0 | 3 |
| 150 | 200 | 0.1 | 8.3 |
| 200 | 200 | 0 | 3 |
| 200 | 20 | −0.1 | 30 |

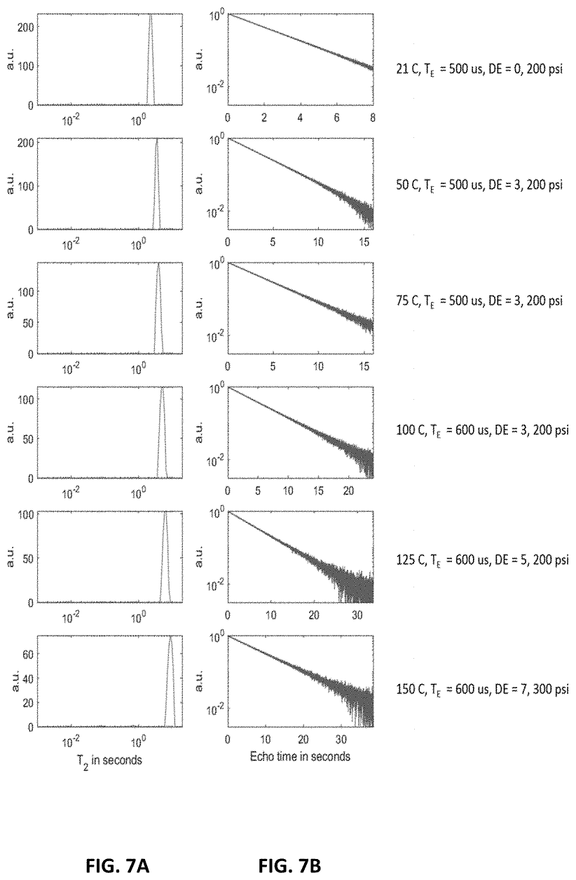

Using the annealed extruded PEEK flowlines or tubes, NMR relaxation measurements were performed on water and dodecane samples from room temperature to 150° C. and from 10 psi to 13,000 psi pressure. FIG. 7A shows a series of six T₂ relaxation spectra for water in an extruded PEEK flowline at different temperatures (ranging from 21° C. to 150° C.) and pressures (ranging from 200 psi to 300 psi) and using different echo spacings (500 μs and 600 μs) and dummy echoes (0, 3, 5, and 7) in the CPMG sequence. Corresponding plots of phased CPMG data are shown in FIG. 7B.

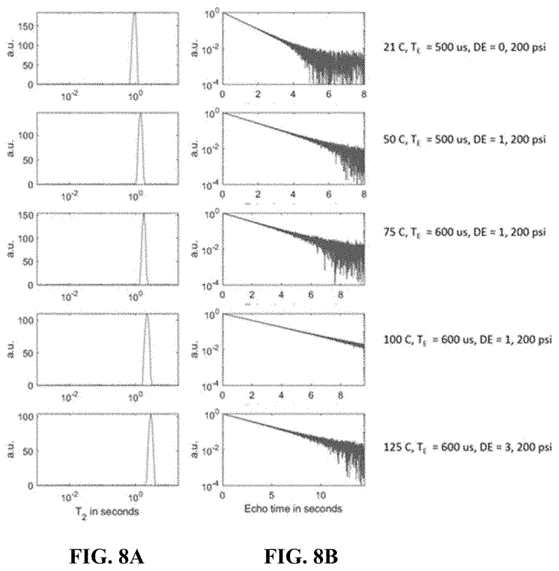

Similarly, FIG. 8A shows the T₂ relaxation spectra of dodecane samples made at temperatures ranging from 21° C. to 150° C., a pressure of 200 psi, different echo spacings (500 μs and 600 μs) and dummy echoes (0, 1 and 3). Corresponding plots of phased CPMG data are shown in FIG. 8B.

It will be appreciated from FIGS. 7A and 7B and FIGS. 8A and 8B that the NMR measurements generated a large T₂ peak with essentially no fast relaxation components; i.e., the spectra were very clean with extremely narrow fluid peaks up to 150° C., at which T₂ was measured at 10 seconds for water (2 seconds for dodecane) with 600 μs echo spacing. It is noted that the main fluid peaks broadened slightly at elevated temperatures, which may be caused by a deteriorated data signal to noise ratio (SNR). The results stand in sharp contrast to the measured T₂ spectra of fluids in machined PEEK probes, as shown in FIGS. 1A and 1B.

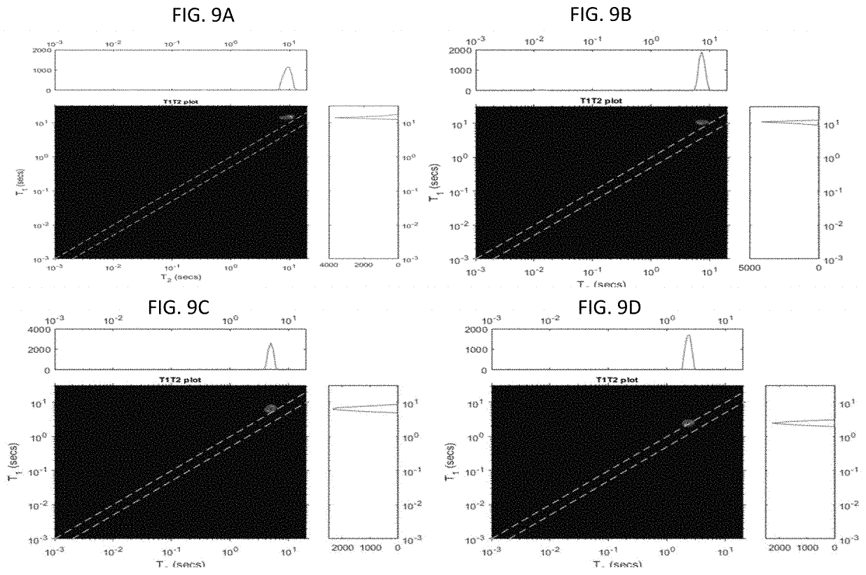

According to one aspect, NMR measurements were conducted to generate T₁-T₂ spectra of the water samples in the annealed extruded PEEK flowlines at a few selected temperature points. FIGS. 9A, 9B, 9C and 9D shows the resulting four different T₁-T₂ spectra at temperatures of 150° C., 125° C., 75° C., and 21° C. In general, it was observed that T₁>T₂ except at room temperatures. The elevated T1/T2 ratio may have a few origins. First, magnet homogeneity deteriorates, and fluid diffusion coefficients increase as a function of temperatures; both factors result in a more prominent diffusion effect at high temperatures. Second, even the same diffusion effect leads to a larger T₂ shortening with an intrinsic longer T₂. In particular, consider two fluid species with T₂=1 second and 10 seconds, respectively. With the diffusion effect adding an additional relaxation of T₂*=100 seconds, the first fluid has a measured T_{2,m}=1/( 1/1+ 1/100)=0.99 seconds, while the second fluid has a measured T_{2,m}=1/( 1/10+ 1/100)=9.1 seconds. Apparently, the diffusion effect takes a greater toll on fluids with longer T₂. Finally, with an intrinsic fluid T₂>10 seconds the measured T₂ was further shortened by phase instability of the oven-controlled oscillator (OCO) (even at 1 ppb phase stability).

NMR relaxation measurements were performed with a few different echo spacings at 125° C. As the echo spacing decreased from 700 to 200 μs, the measured T₂ values monotonically increased from 7 to 8 seconds. This is a near 15% rise, despite that 8 seconds is still 3 seconds short of the measured T₁ of 11 seconds. Some small components of fast relaxation and broadened fluid peaks at short echo spacings were also observed, which may originate from the increased RF duty cycle and from the fact that the pulse and echo spacing are not a multiple of the B₁ pulse period.

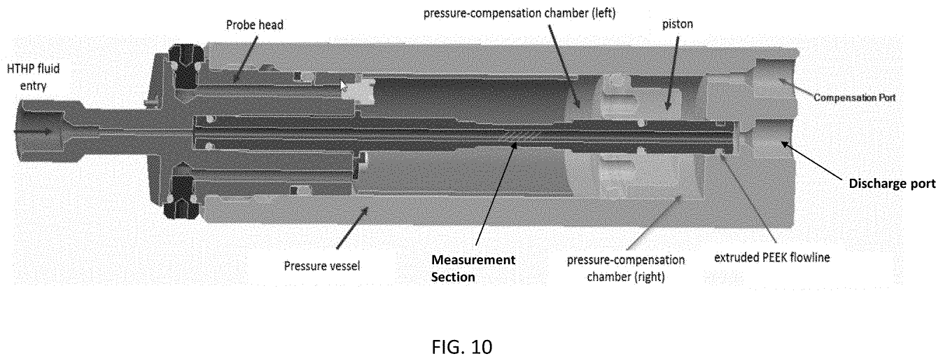

FIG. 10 depicts a cross-section of an extruded PEEK flowline installed in a high pressure high temperature (HPHT) probe. One end of the extruded PEEK flowline is supported by a probe head. The probe head includes a fluid passageway that allows for entry and passage of high temperature high pressure fluids to the inlet (left end) of the extruded PEEK flowline. The probe head also supports a pressure vessel housing that defines a pressure-compensated chamber between the pressure vessel housing and the extruded PEEK flowline. A piston surrounds the opposite end (right end) of the extruded PEEK flowline. The piston is configured to move co-axially along the outer surface of the extruded PEEK flowline in the space between the extruded PEEK flowline and the pressure vessel housing in order to provide for pressure-compensation of the chamber. The opposite end (right end) of the extruded PEEK flowline is fluidly coupled to a discharge port in the pressure vessel housing. The probe can be a component in downhole equipment, such as a downhole NMR sensor for performing NMR measurements on high pressure high temperature fluids, such as formation fluids or borehole fluids.

In an embodiment, a large portion of a probe can be made of nonmagnetic alloys (including both probe head and pressure vessel housing) that can withstand HTHP operations. The sample fluids are introduced into the probe head as depicted in FIG. 10, while measurements are performed on fluids within the measurement section of the extruded PEEK flowline as shown. Although not shot shown, the measurement section can include a miniaturized NMR sensor fixture, such as a permanent magnet (e.g., Halbach-array magnet) and RF coil antenna (or other suitable RF antenna arrangement), that is disposed on the outside of the flowline adjacent thereto. An NMR electronics module (not shown) is electrically coupled to the NMR sensor fixture (particularly, the RF antenna) and configured to perform NMR measurements on the sample fluid in the flowline. For example, the NMR electronics module can include transmitter circuitry that cooperates with the RF antenna to transmit RF pulses of electromagnatic radiation that excite the nuclei of the sample fluid in the flowline. The NMR electronics module can also include receiver circuitry that cooperates with the RF antenna to detect and receive NMR signals that result from the excitation of the nuclei of the sample fluid in the flowline. For example, the NMR electronics module can employ the circuit components described in co-owned U.S. Patent Publication No.: 2017-0248732, entitled “NMR ASIC,” the content of which is herein incorporated by reference in its entirety.

The piston can be configured to equalize pressures across the wall of the extruded PEEK flowline. In this case, the pressure-compensated chamber outside the flowline can be filled with fluid of equal pressure to the fluid in the flowline. The annular space between pressure vessel housing and the flowline can be partitioned into two chambers (left and right) by the piston. To avoid interference with signals from the sampled fluids, the fluid in the left chamber (pressure-compensation chamber) does not include protons. In contrast, the fluid in the right chamber is the same as the flowline fluid, which enters the space through the compensation port. When the operating condition varies, the piston moves so as to maintain pressure equilibrium across the wall of the flowline in the measurement section.

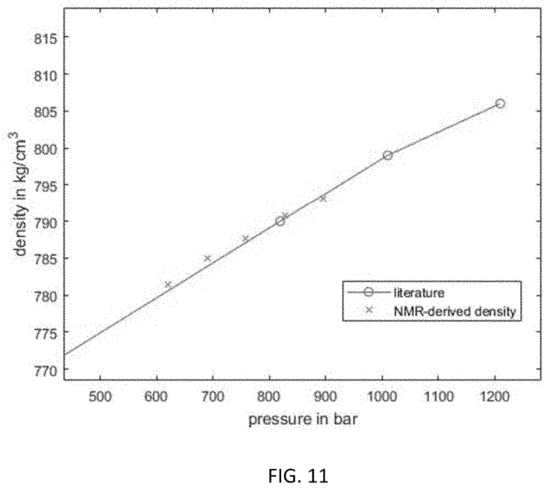

FIG. 11 shows an NMR measurement of dodecane density as a function of pressure in the flowline. In a given CPMG experiment, the amplitude of the NMR signal is directly proportional to the number of protons within the measurement volume. As the volume remains unchanged while varying the fluid pressure, the amplitude becomes a good measure of fluid density of the fluid in the flowline.

In this example, the fluid pressure is increased from 600 bar to 900 bar. Accordingly, the signal amplitude increases by about 1.6%. By scaling the signal amplitude with a constant, the acquired NMR signal data agrees well with reported numbers in the literature. See Caudwell, D. R., et al. “The viscosity and density of n-dodecane and n-octadecane at pressures up to 200 MPa and temperatures up to 473 K”, International Journal of Thermophysics 25.5 (2004): 1339-1352. In practice, the constant can be determined from calibration by measuring the NMR signals with a fluid of known density or by comparing to reported numbers on the fluids of study in previous work.

It should be appreciated that the extruded PEEK, sapphire and YSZ flowlines as described herein are useful in oilfield applications where high temperatures and high pressures may be present. Thus, formation fluids may be more accurately analyzed downhole by locating a downhole nuclear magnetic resonance (NMR) tool in a borehole, with the NMR tool including a small-sized flowline or HPHT probe as described herein. For example, the flowline of the NMR tool can have an inner diameter of less than 0.2 inch and be formed from either extruded polyether ether ketone (PEEK), sapphire, or yttria-stabilized zirconia (YSZ) as described herein. The formation fluid may be flowed into the flowline. Then, the NMR tool may conduct NMR measurements on the fluid in the flowline to analyze the fluid. In alternate embodiments, a small-sized flowline or HPHT probe as described herein can be part of some other downhole NMR equipment or uphole NMR equipment where formation fluid (or produced fluid) are flowed into the flowline. Then, the NMR equipment may conduct NMR measurements on the fluid in the flowline to analyze the fluid.

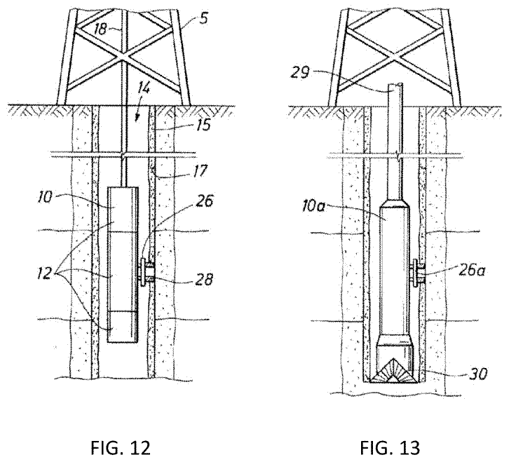

Referring to FIG. 12, an example well site system is shown in which aspects of the present disclosure may be used. In the illustrated example, a downhole wireline tool 10 is provided, which is deployable into the borehole 14 and suspended therein with a conventional wireline 18 below a rig 5 as will be appreciated by one of skill in the art. Alternatively, a conductor or conventional tubing or coiled tubing can be used to deploy the tool 10 in the borehole 14. The downhole tool 10 is provided with various modules and/or components 12, including, but not limited to, a fluid sampling and analysis system 26 used to obtain and analyze formation-fluid samples from the subsurface formation. The system 26 is provided with a probe 28 extendable through the mudcake 15 and to sidewall 17 of the borehole 14. Formation-fluid samples are drawn into the downhole tool 10 through the probe 28. The system 26 also includes flow lines and components that can collect the formation-fluid samples drawn into the downhole tool 10 through the probe 28 and that can perform downhole fluid analysis on formation-fluid samples drawn into the downhole tool 10 through the probe 28.

While FIG. 12 depicts a modular wireline tool for collecting and performing insitu analysis of formation-fluid samples according to one or more aspects of the present disclosure, it will be appreciated by one of skill in the art that such system may be used in any downhole tool. For example, FIG. 13 shows an alternate downhole drilling tool 10a having a fluid sampling and analysis system 26a therein. In this example, the downhole drilling tool 10a including a drill string 29 and a drill bit 30. The downhole drilling tool 10a may be of a variety of drilling tools, such as a Measurement-While-Drilling (MWD), Logging-While Drilling (LWD) or other drilling system. The tools 10 and 10a of FIGS. 12 and 13, respectively, may have alternate configurations, such as modular, unitary, wireline, coiled tubing, autonomous, drilling and other variations of downhole tools.

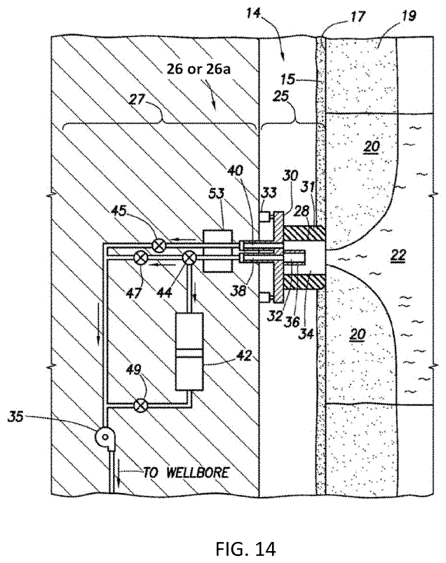

FIG. 14 illustrates an exemplary embodiment of the fluid sampling and analysis system 26 of FIG. 12 or the fluid sampling and analysis system 26a of FIG. 13, which includes an intake section 25 and a flow section 27 for selectively drawing fluid into the desired portion of the downhole tool.

The intake section 25 includes a probe 28 mounted on an extendable base 30 having an outer and inner concentric seals or packers 31, 36 for sealingly engaging the borehole wall 17 around the probe 28. The intake section 25 is selectively extendable from the downhole tool 10 via extension pistons 33. The probe 28 is provided with an interior channel 32 and an exterior channel 34 separated by the wall of the inner seal 36.

The flow section 27 includes a sample line 38 and a guard line 40 driven by one or more pumps 35. The sample line 38 is in fluid communication with the interior channel 32, and the guard line 40 is in fluid communication with the exterior channel 34. The illustrated flow section 27 may include one or more flow control devices, such as the pump 35 and valves 44, 45, 47 and 49 depicted in FIG. 14, for selectively drawing fluid into various portions of the flow section 27. Fluid is drawn from the formation 20 through the interior and exterior channels 32, 34 and into their corresponding flow lines 38, 40.

Initially, an invaded zone 19 surrounds the mudcake 15 and the borehole wall 17. Formation fluid 22 with a sufficiently low level of contamination is located in the formation 20 behind the invaded zone 19. Preferably, contaminated fluid from the invaded zone 19 is drawn through the exterior channel 34 into the guard line 40 and discharged into the borehole 14. Preferably, fluid is drawn into the interior channel 32 through the sample line 38 and either is discharged into the borehole 14 or diverted into one or more sample chambers 42. Once it is determined that the fluid drawn into the interior channel 32 and through the sample line 38 has a sufficiently low level of contamination (and thus is representative of the formation fluid 22), valve 44 and/or valve 49 may be activated using known control techniques to divert the formation fluid from the sample line 38 into the sample chamber(s) 42.

The system 26 is also preferably provided with one or more fluid monitoring systems 53 for analyzing the fluid that enters the probe 28 and flows through the sample line 38 and possibly the guard line 40. The fluid monitoring system 53 may be provided with various monitoring devices or sensors, such as one or more optical spectroscopic analyzers, one or more fluid densiometers, one or more fluid viscometers, and possibly others.

In embodiments, the one or more fluid monitoring systems 53 can include an HPHT probe with small-sized flowline such as described herein with respect to FIG. 10 as part of the sample line 38 (and possibly another HPHT probe with small-sized flowline such as described herein with respect to FIG. 10 as part of the guard line 40). An NMR electronics module (not shown) can be integrated as part of the tool 10 or 10a. The NMR electronics module can interface to the RF antenna (e.g., coil antenna) of the HPHT probe to conduct NMR measurements on the fluid in the flowline to analyze the fluid.

The details of the various arrangements and components of the system 26 described above as well as alternate arrangements and components for the system 26 would be known to persons skilled in the art and found in various other patents and printed publications, such as those discussed herein. Moreover, the particular arrangement and components of the system 26 may vary depending upon factors in each particular design, use or situation. Thus, neither the system 26 nor the present disclosure are limited to the above described arrangements and components and may include any suitable components and arrangement. For example, various geometries for the seals or packers of the probe 28 and corresponding channels can be used and various flow lines, pump placement and valving may be provided for a variety of configurations. Similarly, the arrangement and components of the downhole tool 10 may vary depending upon factors in each particular design, or use, situation. The above description of exemplary components and environments of the tool 10 with which the fluid sampling device 26 of the present disclosure may be used is provided for illustrative purposes only and is not limiting upon the present disclosure.

Although only a few examples have been described in detail above, those skilled in the art will readily appreciate that many modifications are possible in the examples without materially departing from this subject disclosure. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words ‘means for’ together with an associated function.

What is claimed is:

1. A flowline for use in nuclear magnetic resonance (NMR) measurements on fluid, comprising:
an elongate body defining a channel that receives the fluid, wherein the channel has a diameter or maximum width of less than 0.2 inch, and wherein the body comprises a material selected from the group consisting of (i) extruded polyether ether ketone (PEEK), (ii) sapphire, and (iii) yttria-stabilized zirconia (YSZ).

2. The flowline of claim 1, wherein:
the material of the body is extruded PEEK that is subject to annealing.

3. The flowline of claim 2, wherein:
the annealing is carried out at a temperature of 200° C.

4. The flowline of claim 1, wherein:
the material of the body is extruded PEEK and the channel is formed using a through-hole gauge pin.

5. The flowline of claim 1, wherein:
the material of the body is sapphire; and
the channel is formed by grinding or other surface preparation applied to a surface that forms the channel.

6. An apparatus for performing nuclear magnetic resonance (NMR) measurements on fluid, comprising:
an elongate body defining a channel that receives the fluid, wherein the channel has a diameter or maximum width of less than 0.2 inch, and wherein the body comprises a material selected from the group consisting of (i) extruded polyether ether ketone (PEEK), (ii) sapphire, and (iii) yttria-stabilized zirconia (YSZ); and
at least one permanent magnet and an RF antenna disposed adjacent the body.

7. The apparatus of claim 6, wherein:
the RF antenna comprises a coil antenna.

8. The apparatus of claim 6, further comprising:
an NMR electronics module electrically coupled to the RF antenna.

9. Equipment for performing nuclear magnetic resonance (NMR) measurements on formation fluid, comprising:
an elongate body defining a channel that receives the formation fluid, wherein the channel has a diameter or maximum width of less than 0.2 inch, and wherein the body comprises a material selected from the group consisting of (i) extruded polyether ether ketone (PEEK), (ii) sapphire, and (iii) yttria-stabilized zirconia (YSZ); and
at least one permanent magnet and an RF antenna disposed adjacent the body.

10. The equipment of claim 9, wherein:
the RF antenna comprises a coil antenna.

11. The equipment of claim 9, further comprising:
an NMR electronics module electrically coupled to the RF antenna.

12. The equipment of claim 9, wherein:
the formation fluid is at an elevated temperature and pressure corresponding to downhole conditions; and
at least the body is part of a high pressure high temperature probe that includes a probe head that receives the formation fluid at the elevated temperature and pressure and supplies such formation fluid to the body.

13. The equipment of claim 12, wherein:
the probe further includes a pressure compensation chamber surrounding the body with a piston that adjusts pressure in the chamber such that it corresponds to pressure of the fluid in the channel of the body.

14. The equipment of claim 13, wherein:
the piston is configured to move co-axially about the outer surface of the body.

15. The equipment of claim 9, which is configured for performing downhole or uphole NMR measurements on formation fluid.

16. A method of analyzing fluid downhole in a formation traversed by a borehole, comprising:
locating a nuclear magnetic resonance (NMR) tool in the borehole, the NMR tool including a flowline comprising an elongate body defining a channel that receives the formation fluid, at least one permanent magnet and an RF antenna disposed adjacent the body, wherein the channel has a diameter or maximum width of less than 0.2 inch, and wherein the body comprises a material selected from the group consisting of (i) extruded polyether ether ketone (PEEK), (ii) sapphire, and (iii) yttria-stabilized zirconia (YSZ);
flowing fluid into the flowline of the NMR tool; and
using the NMR tool to conduct NMR measurements on the fluid in the flowline, thereby analyzing the fluid.

17. The method of claim 16, further comprising:
measuring fluid density of the fluid in the flowline using an amplitude of an NMR signal.

18. The method of claim 16, wherein:
the RF antenna comprises a coil antenna.

19. The method of claim 16, wherein:
the NMR tool further includes an NMR electronics module electrically coupled to the RF antenna.

20. The method of claim 16, wherein:
the fluid is at an elevated temperature and pressure corresponding to downhole conditions; and
at least the body is part of a high pressure high temperature probe that includes a probe head that receives the fluid at the elevated temperature and pressure and supplies such fluid to the body of the flowline.

21. The method of claim 20, further comprising:
adjusting pressure in a chamber surrounding the body of the flowline such that it corresponds to pressure of the fluid in the channel of the body.

22. The method of claim 21, wherein:
the adjusting employs a piston that moves co-axially about the outer surface of the body.
